(19) United States
(12) Patent Application Publication
(10) Pub. No.: US 2003/0020502 A1
(43) Pub. Date: Jan. 30, 2003

(54) Contact probe member and manufacturing method of the same

(76) Inventors: Osamu Sugihara, Kofu-shi (JP); Nobuhiko Suzuki, Osaka (JP)

Correspondence Address: Gregory P. LaPointe, BACHMAN & LaPOINTE, P.C., Suite 1201, 900 Chapel Street, New Haven, CT, 06510-2802, US

(21) Appl. No.: 10/201,867

(22) Filed: Jul. 23, 2002

(30) Foreign Application Priority Data
Jul. 26, 2001 (JP) 2001-226254

(51) Int. Cl. G01R 31/02

(52) U.S. Cl. 324/754

(57) ABSTRACT

There is disclosed a contact probe member which solves a problem of reflection in a terminal of an electrical transmission line. The contact probe member comprises: a plurality of electrodes which corresponds to pads in a semiconductor device disposed on an insulating substrate; and a plurality of electrical transmission lines disposed on the insulating substrate and electrically connected to the plurality of electrodes, wherein a terminating resistance 80 is disposed in a terminal a of the electrical transmission line in order to prevent reflection from the terminal of the electrical transmission line.

### REFERENCE TO RELATED APPLICATION

This application claims the priority right under Paris Convention of Japanese Patent Application No. 2001-226254 filed on Jul. 26, 2001, the entire disclosure of which is incorporated herein by reference.

### BACKGROUND OF THE INVENTION

1. Field of the Invention

The present invention relates to a contact probe member for use in testing (checking) a semiconductor device.

2. Description of the Prior Art

The checking of the semiconductor device is roughly divided into a product check (electric characteristics test) by a probe card, and a burn-in test as a reliability test performed after the product check.

The electric characteristics test by the probe card is conducted for each chip on a wafer. Types of the probe card include: a probe card shown in FIGS. 9A and 9B in which an opening 62 is formed in a center portion of a multilayered wiring substrate 61 formed of a glass epoxy resin, probes 63 are arranged to extend toward the center of the opening 62 from a periphery of the opening 62, and the probes 63 are brought into contact with an electrode terminal 42 on one chip 41 of a wafer 40 in order to perform the check; and a membrane probe card shown in FIG. 10 in which a bumped membrane 70 constituted by arranging bumps 72 (convex contact points) on one surface of a membrane 71 of polyimide is used as a contact component. In FIG. 10, the bumps 72 are electrically connected to a wire 74 via through holes 73 formed in the membrane 71, and portions with the bumps 72 formed therein are pressed into contact via an elastic member 75, pivot mechanism 76, and leaf spring 77.

The burn-in test is one of screening tests performed in order to remove a semiconductor device having an inherent defect or a device causing a trouble dependent on time and stress because of a manufacturing dispersion. The check by the probe card is the electric characteristics test of the manufactured device, whereas the burn-in test may be referred to as a heat acceleration test.

The burn-in test has an insufficient practicability in a cost respect in a usual method (one chip burn-in system) of: conducting the electric characteristics test on each chip by the probe card; and subsequently conducting the burn-in test on each chip, in which the wafer is cut into chips by dicing and the chips are packaged. To solve the problem, development and practical use of a wafer level contact board (burn-in board) for collectively conducting one burn-in test on a large number of semiconductor devices formed on the wafer have been advanced (Japanese Patent Application Laid-Open No. 1995-231019). The wafer level burn-in system using the wafer level contact board has a high practicability in the cost respect, and is further an important technique such that an up-to-date technical flow including a bare chip shipping and mounting can be realized.

As compared the conventional probe card, the wafer level contact board is different in required characteristics and high in required level, in that the wafers are checked in a bulk and the board is used in a heating test. When the wafer level contact board is practically used, it is also possible to conduct the product test (electric characteristics test) heretofore performed by the conventional probe card on the bulk of wafers.

FIG. 11 shows one concrete example of the wafer level contact board.

As shown in FIG. 11, the wafer level contact board has a structure in which a membrane ring having bumps 30 is fixed onto a multilayered wiring substrate for the wafer level contact board (hereinafter referred to as the multilayered wiring substrate) 10 via an anisotropic conductive rubber member 20.

The membrane ring having bumps 30 has a contact portion which directly contacts an element to be tested. In the membrane ring having bumps 30, bumps 33 are formed on one surface of a membrane 32 extended in a ring 31, and pads 34 are formed on the other surface. The same number of bumps 33 as that of pads are formed in positions arranged correspond to electrode terminals formed on a peripheral edge or a center line of each semiconductor device on a wafer 40. About 600 to 1000 pins of electrode terminals are arranged for one chip, and the number of pads, which is multiplied by the number of chips, are arranged on the wafer.

In the multilayered wiring substrate 10, wires and pad electrodes (not shown) for giving predetermined burn-in test signals to the respective bumps 33 isolated on the membrane 32 via the pads 34 are disposed on an insulating substrate. The multilayered wiring substrate 10 has a multilayered wiring structure because the wiring is complicated.

The anisotropic conductive rubber member 20 is an elastic member which has conductivity only in a main surface and vertical direction, which is formed of a silicon resin, and in which metal particles are buried in pad electrode portions. The member electrically connects pad electrodes (not shown) on the multilayered wiring substrate 10 to the pads 34 on the membrane 32. The anisotropic conductive rubber member 20 abuts on the pads 34 on the membrane 32 via convex portions (not shown) formed on opposite surfaces, thereby absorbs height dispersions of concaves/convexes on the surface of the wafer 40 and bumps 33, and securely connects the pads on the semiconductor wafer to the bumps 33 on the membrane 32.

The electrode terminals serving as a power supply of an integrated circuit, ground, and input/output terminal of the signal (a power supply terminal, ground terminal, and signal (I/O) terminal) are formed in the respective semiconductor devices (chips). Bump electrodes of the wafer level contact board are formed and connected in a one-to-one correspondence with respect to all the electrode terminals of the semiconductor chip. Moreover, in the multilayered wiring substrate in the wafer level contact board, common wires are disposed for a power supply wire, ground wire and signal wire in order to decrease the number of wires.

However, the above-described contact probe member has the following problems.

In FIG. 2, a terminal (tail end) a of a signal common wire 1′ unconnected to another line or another apparatus has a problem that a signal (traveling wave) inputted from a tester on a transmission side is reflected and the traveling wave and reflected wave are synthesized to generate a noise (ringing).

Similarly, the reflection occurs in a characteristic impedance mismatched position. When the reflection occurs, a transmission amount of a signal wave is lost and the signal wave is strained. Concretely, there is a problem that the reflection occurs in connected positions to lines having different characteristic impedances in the multilayered wiring substrate 10, such as a branch position b of signal common wires 1, 1′, branch positions c, d, e, c′, d′, e′ from the signal common wires 1, 1′, connected positions of branch wires to the pad electrodes (not shown) on the multilayered wiring substrate, and connected positions by the through holes (not shown) of the signal common wires. Similarly, there is a problem that the reflection occurs in the connected positions to the apparatuses having different characteristic impedance in a wafer level contact board 50, such as the pads and bumps (not shown) on the anisotropic conductive rubber member 20 and membrane ring having bumps 30.

Moreover, there is also a problem that a crosstalk between the signal wires occurs by a noise generated by the reflected wave.

Furthermore, electrically to an inlet (outer peripheral pad) of the multilayered wiring substrate 10 from the tester on the transmission side, a resistance of cable, open short, and the like have heretofore been calibrated in the tester and assured every time. However, for the above-described causes, it has been impossible to assure the wire resistance, open short, and the like in the multilayered wiring substrate 10 by the calibration by the tester.

This similarly applies to the probe card.

### SUMMARY OF THE INVENTION

The present invention has been developed under the above-described background, and a first object thereof is to provide a contact probe member which solves a problem of reflection in a terminal of an electrical transmission line.

Moreover, a second object of the present invention is to provide a contact probe member which solves problems in characteristic impedance mismatched positions.

Furthermore, a third object is to provide a manufacturing method in which the contact probe member can be realized in a simple process without adding a complicated process.

To achieve the objects, according to the present invention, there are provided the following constitutions.

Constitution 1

A contact probe member comprising:

a plurality of electrodes which corresponds to electrode terminals in a semiconductor device disposed on an insulating substrate; and

a plurality of electrical transmission lines disposed on the insulating substrate and electrically connected to the plurality of electrodes,

wherein a terminating resistance is disposed in a terminal of the electrical transmission line in order to prevent reflection from the terminal of the electrical transmission line.

Constitution 2

The contact probe member according to constitution 1 wherein the terminating resistance is disposed between the terminal of a signal wire and a GND or a GND wire.

Constitution 3

A multilayered wiring substrate which constitutes a part of a wafer level contact board use for testing together a large number of semiconductor devices formed on a wafer, the multilayered wiring substrate comprising:

a plurality of electrodes which corresponds to electrode terminals on the large number of semiconductor devices disposed on the multilayered wiring substrate;

common wires of each signal, power supply, and GND, which electrically connect the electrodes to one another in common in order to connect the same signal, power supply and GND to the same positions in each of the large number of semiconductor devices;

branch wires which are branched from the common wires, and which connect the electrodes to the common wires; and

a terminating resistance disposed between the terminal of the signal common wire and the GND common wire.

Constitution 4

A probe structure of a contact probe member comprising:

a plurality of electrodes which corresponds to electrode terminals in a semiconductor device disposed on an insulating substrate; and

a plurality of electrical transmission lines disposed on the insulating substrate and electrically connected to the plurality of electrodes,

wherein a resistance for matching a characteristic impedance is disposed in a connected position to a line having a different characteristic impedance in the electrical transmission line and/or a connected position to an apparatus having a different characteristic impedance.

Constitution 5

A wafer level contact board comprising: at least a multilayered wiring substrate for the wafer level contact board; and a membrane ring having bumps serving as a contact portion which directly contacts an element to be tested,

wherein a resistance for matching a characteristic impedance is disposed in a connected position to a line having a different characteristic impedance in an electrical transmission line in the wafer level contact board and/or a connected position to an apparatus having a different characteristic impedance.

Constitution 6

A manufacturing method of a contact probe member, comprising: a step of forming a wire layer or a metal layer having a single layer structure or a multilayered structure in which two or more different material layers are laminated on an insulating substrate; and a step of etching the wire or metal layer to form a wire (including an electrode) and/or an isolated electrode, the method further comprising:

a step of etching the wire or metal layer in a portion in which a resistance is to be formed in the wire or metal layer and disposing the resistance constituted of a part of the wire or metal layer.

According to the constitution 1, the terminating resistance is disposed in the terminal (tail end) of the electrical transmission line in order to prevent the reflection from the terminal of the electrical transmission line in the contact probe member. Thereby, there can be provided the contact probe member which solves the problem of the reflection in the terminal of the electrical transmission line.

Concretely, for example, as described in the constitution 2, a terminating resistance 80 is disposed between a terminal a of the signal common wire and the GND or the GND wire as shown in FIG. 1, so that the problem of the reflection in the terminal a of the electrical transmission line can be solved. Similarly, the terminating resistance 80 is disposed between the terminal a of the signal common wire and the GND common wire as shown in FIG. 3, so that the problem of the reflection in the terminal a of the electrical transmission line can be solved. In these cases, when there are a plurality of terminals of the signal common wires, the terminating resistances are disposed in the respective terminals. When there are terminals in the respective layers in the multilayered wiring substrate, the terminating resistances are disposed in the terminals of the respective layers.

The contact probe member described in the constitution 1 includes a probe card, wafer level contact board, multilayered wiring substrate for the wafer level contact board, and the like. The electrode described in the constitution 1 includes a pad, bump, and the like. The insulating substrate described in the constitution 1 includes: a material having flexibility (resin substrate, resin film, and the like); and a material having no flexibility (glass, ceramic substrate, and the like). The constitution 1 includes a case in which the electrode disposed on one side of the insulating substrate is connected to the wire disposed on the other side of the insulating substrate via through holes. The constitution 1 also includes: a single layer wire, not a multilayered wire; and a case in which the common wire is not disposed (a case in which individual wires to the electrodes are disposed). This also applies to the constitution 4 described later.

Similarly as described above, according to the constitution 3, there can be provided the multilayered wiring substrate for the wafer level contact board, which solves the problem of reflection in the terminal of the electrical transmission line.

Additionally, with a design in which the terminal is not generated, such as a point e in FIG. 2, the problem of reflection in the terminal can be solved.

According to the constitution 4, the resistance for matching the characteristic impedance is disposed in the connected position to the line having the different characteristic impedance in the electrical transmission line, and/or the connected position to the apparatus having the different characteristic impedance. Thereby, the reflection in the characteristic impedance mismatched point can be prevented, and the loss of transmission amount of the signal wave to the subsequent line or apparatus, or the strain of the signal wave can be prevented.

The contact probe member described in the constitution 4 includes a probe card, wafer level contact board, multilayered wiring substrate for the wafer level contact board, membrane ring having bumps for the wafer level contact board, anisotropic conductive rubber member, and the like.

Similarly as described above, according to the constitution 5, there can be provided the wafer level contact board which solves the problem of reflection in the characteristic impedance mismatched point of the electrical transmission line.

For the resistance for matching the characteristic impedance, for example, as shown in FIG. 1, the resistance having the same value as that of the characteristic impedance of the electrical transmission line before the connected position is disposed between connected positions to lines having different characteristic impedances in the electrical transmission line, such as a branch position b of signal common wires 1, 1′, branch positions c, d, e, c′, d′, e′ from the signal common wires 1, 1′, connected positions of branch wires to the pad electrodes (not shown) on the multilayered wiring substrate, and connected positions by the through holes (not shown) of the signal common wires, and the GND (or the power supply). Similarly, the resistance having the same value as the value of the characteristic impedance of the electrical transmission line before the connected position is disposed between the pad or bump (not shown) on the apparatus having the different characteristic impedance, such as the anisotropic conductive rubber member 20 and membrane ring having bumps 30, and the GND (or the power supply). Thereby, a current flows through the resistance in the connected position and the characteristic impedance is matched.

Additionally, the above-described problem can be solved by the design in which the characteristic impedance in the connected position is matched.

According to the constitution 6, the method comprises the step of etching the wire or metal layer in the portion in which the resistance is to be formed in the wire or metal layer having the single layer structure or the multilayered structure with two or more different material layers laminated therein, and disposing the resistance constituted of a part of the wire or metal layer. Therefore, the contact probe member having the resistance can be realized in the simple step without adding any complicated step.

In this case, for example, the resistance portion is formed into the metal layer constituting a lowermost layer of the wire or metal layer having the multilayered structure. Thereby, the resistance can directly be formed on the substrate, the resistance well adheres, and the resistance having a height (thickness) which causes no trouble in the contact can be formed.

Additionally, in the constitution 6, it is preferable to form the sectional structure of the wire or metal layer as a laminate structure including two or more different metal materials. It is also preferable that at least the metal constituting the resistance and the metal formed on the resistance are of different types. In this case, it is preferable to select materials which have different selection ratios in a dry etching or a wet etching. That is, it is preferable to select a type of an etching solution of the metal constituting the resistance, different from a type of an etching solution of the metal formed on the resistance, so that the former metal is not etched by the etching solution of the latter metal. For example, Ni or Cu is etched by ferric chloride or nitric acid, and Cr is etched by another etching solution. Then, only Cr can preferably be left. Moreover, CrN (N accelerates the etching), and CrO (O retards the etching) are used. For example, a structure of CrN (metal constituting a main wire material)/CrO (metal constituting the resistance) is possible.

Additionally, in the above-described respective constitutions, since the terminating resistance is disposed and the characteristic impedance is matched as described above, the noise (ringing) by the reflection can be reduced, a transmission loss can also be reduced, and an accurate measurement (check) of the device is possible as compared with the conventional art.

Moreover, since the terminating resistance is disposed and the characteristic impedance is matched, the constitution extending to the measurement end of the contact probe member from the tester can be assured by calibration by the tester. For example, a tester including a function of a TDR oscilloscope is used to measure transmission characteristics of a signal line (attenuation and impedance of a signal voltage), and the calibration of each signal line is possible based on measurement results. Moreover, when the respective signal lines have different wire lengths, the wire lengths of the signal lines are measured, and thereby the timing of each signal can be adjusted.

Additionally, when a GND layer is formed in a broad range on the multilayered wiring substrate in each of the above-described constitutions, that is, when a so-called solid GND layer is formed, a through hole is formed between the terminal or the connected position and the GND layer, and the resistance can be formed in the through hole.

### BRIEF DESCRIPTION OF THE DRAWINGS

FIG. 1 is a schematic diagram showing one embodiment in which a terminating resistance is disposed in a terminal of an electrical transmission line.

FIG. 2 is a schematic diagram showing reflection in the terminal of the electrical transmission line.

FIG. 3 is a schematic diagram showing another embodiment in which the terminating resistance is disposed in the terminal of the electrical transmission line.

FIG. 4 is a main part sectional view of a wire or metal layer having a multilayered structure.

FIG. 5 is a main part sectional view showing that a resistance is formed from the wire or metal layer having the multilayered structure.

FIG. 6 is a main part sectional view showing a manufacturing process of a multilayered wiring substrate according to one embodiment of the present invention.

FIG. 7 is a sectional view showing a step of forming a membrane ring in one embodiment of the present invention.

FIG. 8 is a main part sectional view showing a step of processing the membrane ring in one embodiment of the present invention.

FIG. 9 shows explanatory views of one mode of a probe card, FIG. 9A is a plan view, and FIG. 9B is a sectional view.

FIG. 10 is a partial sectional view showing another mode of the probe card.

FIG. 11 is a schematic diagram of a wafer level contact board.

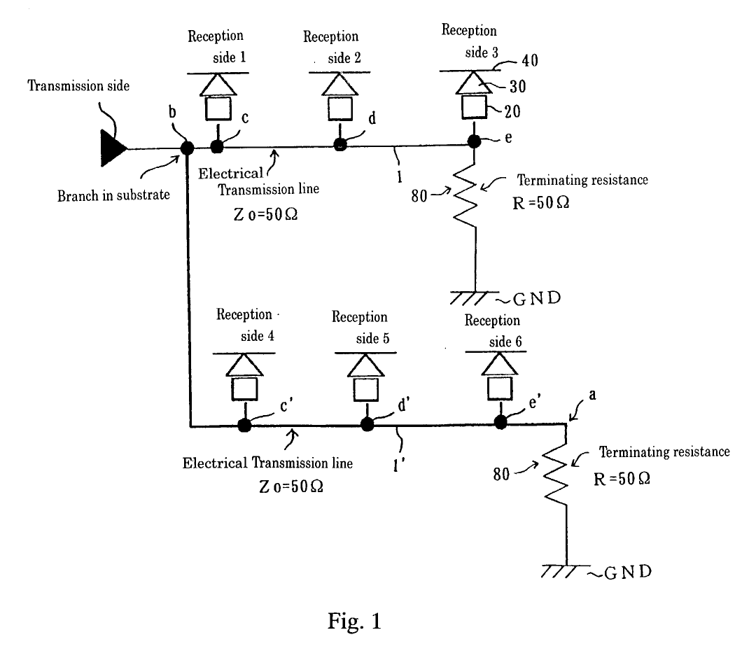

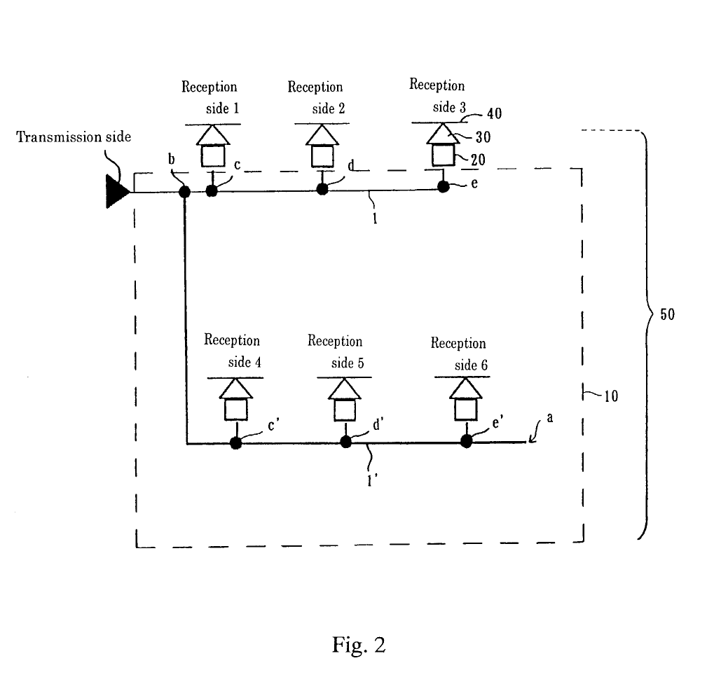

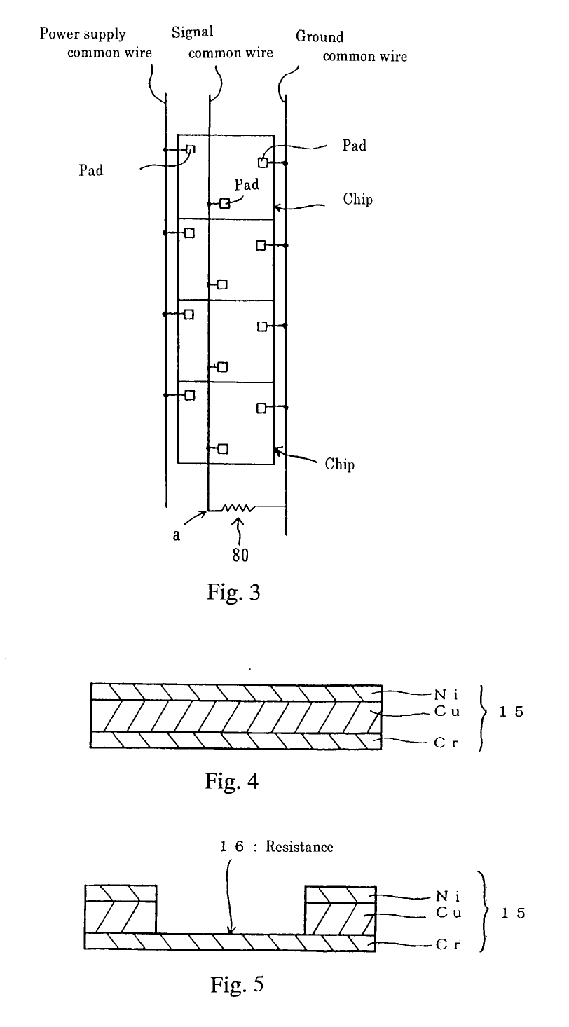

### DESCRIPTION OF THE PREFERRED EMBODIMENT

An embodiment of the present invention will be described hereinafter with reference to the accompanying drawings.

In the present invention, a resistance forming method is not particularly limited, but it is preferable to etch a wire or metal layer disposed on an insulating substrate and dispose a resistance constituted by a part of the wire or metal layer in a manufacturing process of a contact probe member.

For example, with respect to a wire or metal layer 15 having an Ni/Cu/Cr multilayered structure as shown in FIG. 4, Ni/Cu are etched/removed in a portion of the wire or metal layer (a portion in which the resistance is to be formed), only a lowermost layer of Cr is left, and this Cr portion can be formed as a resistance 16 as shown in FIG. 5.

When the thin-film resistance is formed of the lowermost layer of Cr in this manner, the resistance having a height (thickness) can be formed without any trouble in a contact. Moreover, the resistance can be formed so that an adhesion of Cu to a substrate is enhanced without adding many complicated steps to usual steps of a multilayered wiring substrate. This can also apply to a manufacturing process of the contact probe member including a probe card (including a step of etching the wire layer and forming a wire) and a membrane ring having bumps for a wafer level contact board (including a step of etching the metal layer and forming an electrode (metal pad)). For example, in FIG. 5, when a right-side Ni/Cu/Cr portion forms a terminal of a signal common wire, and a left-side Ni/Cu/Cr portion forms a GND common wire, a terminating resistance can be formed between the portions. Similarly, in FIG. 5, when the right-side Ni/Cu/Cr portion forms an isolated signal pad in the membrane ring having bumps for the wafer level contact board, and the left-side Ni/Cu/Cr portion forms an isolated GND pad, the terminating resistance can be formed between the portions.

In general, a resistance value of a resistance element can be determined by a width, length, thickness, and specific resistance. However, in a semiconductor device, capacity increase and high integration have been advanced, and most of pitches of wires are determined. Therefore, it is difficult to adjust the resistance value with a wire width or length. Under this situation, to control the resistance value, Cr is originally used as a lowermost layer of the wire having the Ni/Cu/Cr multilayered structure for a purpose of an adhesion strength. In this case, depending on forming conditions of Cr, Cr is formed in a relatively thin film, for example, of 300 to 400 angstroms. Therefore, it is relatively easy to control and raise the resistance value. In one embodiment of the present invention, Cr present in the lowermost layer also serves as the resistance element. In this case, the enhancement of adhesion of the substrate to the wire and the function of the resistance element can simultaneously be achieved. Additionally, a reason why only the lowermost layer of Cr is left is that a high resistance can preferably be formed in forming the resistance of a Cr single layer rather than in forming the resistance of a two-layers structure including Cu as a metal for easily passing a current, and Cr.

The resistance value of the Cr thin-film resistance can be adjusted by a film forming method, film forming conditions (including the introduction of impurities), adjustment of a film thickness or a resistance element size (width, length), and the like.

The resistance value of the Cr thin-film resistance can be adjusted, for example, by adjusting film thickness by a sputter method for the following reason. First in a sputtering, when the sputtering is started, an impurity gas exists in a chamber, and a thin film formed in an initial sputter time is oxidized and nitrided by an influence of impurity gas. That is, when an in-line sputter apparatus is used to perform the sputtering, the impurity gas in the chamber in the initial sputter time is mixed as an impurity in the film. Alternatively, some material is adsorbed by the substrate before the sputtering regardless of the use of the in-line sputter apparatus and the material is supposedly mixed as the impurity in the film during the sputtering. That is, as a result, for example, Cr formed into the film by the sputtering in this manner can be said to have a resistance value higher than a value of the specific resistance of bulk Cr. Therefore, when the thin film is formed by the sputtering, the impurity is supposedly mixed in the film in many cases. The Cr thin film has a high resistance value, a resistance value close to a desired value can be obtained with the thin film, and therefore the film can preferably be used as the resistance element.

The resistance value of the Cr thin film can also be adjusted by positively mixing another component into the Cr thin film. That is, for Cr, the impurity is mixed and the resistance value changes in accordance with the film forming conditions. Therefore, to form the Cr film, another component is positively mixed into the Cr thin film, and the amount of the component is adjusted during the sputtering. Thereby, the resistance value is adjusted and the desired resistance value can be obtained. That is, the Cr thin film is subjected to: a reactive sputtering using gases such as CO₂, O₂, N₂, CO, NO₂, and NOCH₄; or a sputtering using a nonmetal as the impurity in a target composition, that is, a sputtering using targets such as CrO, CrN, and CrSi. Thereby, CrO, CrN, CrSi, and the like are formed, a content of O, N, or Si is adjusted, and the resistance value in the resistance elements can be adjusted. Additionally, when the film is formed by the sputter method using Si as a composition in the target, and when a chrome silicide (CrSi) target and Ar gas are used, the resistance element is formed of CrSi. For CrSi, the resistance value can be controlled by adjusting the amount of Si. Thereby, the resistance value of the thin-film resistance can be enhanced.

The resistance value of the Cr thin-film resistance can also be adjusted by the size (width, length) of the resistance element.

For example, the linear width of the Cr thin-film resistance is inversely proportional to the resistance value, and the resistance value can be adjusted by the width of the resistance element. Moreover, for example, the value is 30 ohms with a wire length of 100 μm, and 60 ohms with a wire length of 200 μm. As seen from this, the resistance value in the resistance element can be adjusted by the length of the resistance element. Therefore, the dimension (width, length, thickness) of the resistance may be determined in accordance with the desired resistance value (e.g., 10 to 500 Ω). Additionally, a specific resistance is preferably high, and the dimension of the resistance element is limited by the material. Moreover, the resistance element cannot be formed with a wire width of an order of millimeters from an area restriction. Therefore, the linear width is suppressed in a range of several tens of micrometers to 200 μm.

The Cr thin-film resistance can be formed with a wire length of several micrometers to several millimeters, wire width of 10 μm to 10 mm, and thickness of 30 to 500 angstroms. The thickness of the Cr thin-film resistance depends on the sputter apparatus for use in forming the Cr thin-film resistance, and is not generally limited. Moreover, the resistance thickness can variously be selected in accordance with a vacuum degree and a stability of plasma in the Cr thin film forming conditions, but is preferably set to 50 angstroms or more from a viewpoint of adhesion, and is preferably set to 30 to 2000 angstroms, particularly when the in-line sputter apparatus is used.

Examples of the material for forming the resistance and replacing Cr include W, Ti, Al, Mo, Ta, CrSi, and the like. A film thickness is, for example, in a range of 30 angstroms to several micrometers. Additionally, the film thickness is determined from a space (area: width, length) which forms the resistance so as to satisfy the required resistance value.

Examples of a material replacing Cu as a main wire material include Al, Mo, and the like. The film thickness is, for example, in a range of 0.5 μm or more, preferably 2 to 6 μm. When molybdenum is used, the film thickness needs to be three or more times the thickness of Cu in order to achieve the same sheet resistance. Additionally, with Mo, the dry etching is possible.

Examples of a material replacing Ni include metals having a high adhesion in a relation with materials forming upper and lower layers. The film thickness of Ni is, for example, in a range of 0.1 μm or more, preferably 0.2 to 0.4 μm.

Examples of the etching solution or method of Al include: a mixed etching solution of phosphoric acid, nitric acid, acetic acid, and water; a mixed etching solution of hydrofluoric acid, nitric acid, and water; an anode oxidation method; a plasma etching using etching gases such as CCl₄ and BCl₃; and the like.

Examples of the etching solution or method of W include: a red prussiate (potassium ferricyanide) etching solution; plasma etching using etching gases such as CF₄; and the like.

Examples of the etching solution or method of Mo include: a mixed etching solution of phosphoric acid, nitric acid, and water; etching solutions such as a fluoride solution; plasma etching using etching gases such as CF₄, CCl₄+O₂, CHF₃, and CH₂F₂; and the like. Examples of the etching solution of MoSi include a fluorine-based etching solution, and the like.

Examples of the etching solution or method of Ti include: a mixed etching solution of hydrofluoric acid, nitric acid, and water; plasma etching using etching gases such as CF₄ and CBrF₄; and the like.

Examples of the etching solution or method of Ta include: a mixed etching solution of an aqueous NaOH solution and hydrogen peroxide solution; plasma etching using etching gases such as CF₄; and the like.

The layers of Au, AuCo alloy, platinum, platinum rhodium, rhodium, palladium, and the like can be formed on the surface of the wire (including the electrode) or the isolated electrode for purposes of reduction of a contact resistance, enhancement of a resistance to oxidation, enhancement of a surface hardness, and the like. These layer can be formed on the surface of the wire layer or electrode, for example, in electroless or electrolytic plating.

Additionally, examples of another embodiment of the resistance forming method include: (1) a method of reducing the thickness of the wire or metal layer having the single layer structure (Cu, Cr, Mo, Si, Ta, W, Al, oxide (ITO, SnO₂), and the like) or the thickness of the wire or metal layer having the multilayered structure (thickness of a particularly main wire material layer or the like) by the etching in the portion in which the resistance is to be formed; (2) a method of forming a wire resistance having a small linear width in the portion in which the resistance is to be formed; (3) a method of depositing a resistance material in the portion in which the resistance is to be formed and forming the resistance (e.g., a liftoff method); (4) a method of printing the resistance material in the portion in which the resistance is to be formed and forming the resistance; (5) a method of attaching a chip resistance to the portion in which the resistance is to be formed; and the like.

Additionally, in a method of forming the resistance element and subsequently depositing the metal on the resistance element (e.g., depositing Cr by laser CVD), the resistance value is measured, and subsequently the resistance can finely be adjusted. Alternatively, in a method of adjusting the width of the element (e.g., depositing Cr by the laser CVD, or shaving Cr), after checking the resistance value, the resistance can finely be adjusted.

Examples will be described hereinafter.

### EXAMPLE 1

Preparation of Multilayered Wiring Substrate

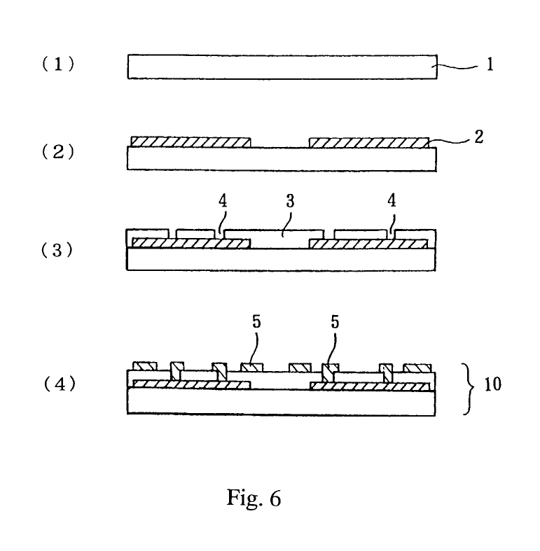

FIG. 6 is a main part sectional view showing one example of a manufacturing process of the multilayered wiring substrate.

On one surface of a glass substrate 1 obtained by polishing the surface shown in a step (1) of FIG. 6 to be flat (manufactured by HOYA Corp.: NA of 40, size of 320 mm square, thickness of 3 mm), a Cr film was formed in a thickness of about 400 angstroms, a Cu film was successively formed in about 5.0 μm, and an Ni film was successively formed in about 0.3 μm by the sputter method, and an Ni/Cu/Cr multilayered metal layer (not shown) was formed. In this case, the Cr film had a sheet resistance of 30 Ω.

Here, Cr is disposed in order to strengthen an adhesive force of glass to Cu. Moreover, Ni is disposed in order to prevent Cu from being oxidized, to strengthen the adhesive force of Cu to a resist, and to prevent polyimide from remaining in a bottom portion of a contact (via) hole by reaction of Cu with polyimide.

Additionally, the method of forming Cu and Ni is not limited to the sputter method, and may be an electrolytic plating method. Moreover, an Au film may also be formed on the Ni film by the sputter method or the electrolytic or electroless plating method, so that the contact resistance can be reduced.

Subsequently, as shown in a step (2) of FIG. 6, a predetermined photolithography process (resist coat, exposure, development, etching) is performed, an Ni/Cu/Cr multilayered wire layer is patterned, and a first layer of wire pattern 2 is formed. Additionally, in the multilayered wire layer, a portion in which a terminal resistance between the terminal of the signal common wire and the GND common wire is to be formed is not patterned, and the wire is left therebetween.

In detail, first the layer is coated with a resist (manufactured by Cypray Co.: Microposit S1400) having a thickness of 3 μm, and baked at 90° C. for 30 minutes. A predetermined mask is used to expose the resist, an image is developed, and a desired resist pattern (not shown) is formed. This resist pattern is used as the mask, and the etching solution of ferric chloride is used to etch the Ni/Cu layer. The etching solution of cerium ammonium nitrate, chromate, aqueous permanganate, or the like is used to etch the Cr layer. Subsequently, a resist peel solution is used to peel the resist, the layer is water-washed and dried, and the first layer of wire pattern 2 is formed.

Formation of Resist Portion

Subsequently, for the wire portion formed between the terminal of the signal common wire and the GND common wire in the first-layer wire pattern 2 having the Ni/Cu/Cr multilayered structure in the above-described step, as shown in FIGS. 4 and 5, the Ni/Cu layer is etched and a Cr thin-film terminating resistance 16 is formed. In this case, the terminating resistance was disposed in all terminals of a plurality of signal common wires. In this case, for the Cr thin-film terminating resistance, the wire length was set to 167 μm, the wire width was set to 100 μm, and the resistance value was set to 50 Ω. Additionally, the signal common wire had a characteristic impedance of 50 Ω.

The above-described step will concretely be described. The first-layer wire pattern 2 is coated with the resist, the predetermined mask is then used to exposure and develop the image, and the resist pattern is used by removing the resist from only the portion in which the Cr thin-film terminating resistance is to be formed. Subsequently, the resist pattern is used as the mask, the etching solution of aqueous ferric chloride is used, Ni/Cu are etched, and the Cr thin-film terminating resistance is formed.

Additionally, the method of forming the Cr thin-film terminating resistance is not limited to the above-described method. For example, to form the first-layer wire pattern 2, also for the portion in which the terminating resistance is to be formed between the terminal of the signal common wire and the GND common wire, the Ni/Cu layers are simultaneously etched, and only this portion is protected by the resist. Subsequently, the Cr layer is etched to form the wire pattern 2, and the Cr thin-film terminating resistance can be formed in the portion protected by the resist.

Subsequently, as shown in a step (3) of FIG. 6, a spinner is used to apply a photosensitive polyimide precursor in a thickness of 10 μm on the first-layer wire pattern 2, and a polyimide insulating layer 3 is formed. Contact holes 4 are formed in the polyimide insulating layer 3.

In detail, the applied photosensitive polyimide precursor is baked at 80° C. for 30 minutes, the predetermined mask is used to expose and develop the image, and the contact holes 4 are formed. The photosensitive polyimide precursor is cured at 350° C. for four hours in a nitride atmosphere and completely formed into polyimide. Subsequently, the surface of polyimide is formed into a coarse surface by an oxygen plasma treatment so that the adhesive force to a second wire layer formed in the next step is enhanced. Additionally, organic materials such as polyimide in each contact hole 4 and a residual of a developer are oxidized and removed.

Subsequently, similarly as the steps (1) and (2), a second Ni/Cu/Cr multilayered wiring layer (not shown) is formed and patterned, and contact pads 5 are formed as shown in step (4) of FIG. 6.

Finally, for a purpose of enhancing an electric contact property of each contact pad 5 with an anisotropic conductive rubber member, an Au film was formed in a thickness of 0.3 μm on the Ni film by the electroless plating method. Additionally, the Ni film has a function of strengthening the adhesive force of the Au film to Cu.

Moreover, the substrate is coated with polyimide as the insulating film, and the film is patterned so that a protective insulating film can be formed.

Through the above-described steps, a multilayered wiring substrate for a wafer level contact board 10 was obtained.

Attachment of Anisotropic Conductive Rubber Member

Subsequently, the anisotropic conductive rubber member formed of a silicon resin and having metal particles buried in a pad electrode portion was attached to a predetermined position of the multilayered wiring substrate for the wafer level contact board 10.

Preparation of Membrane Ring

Subsequently, a membrane ring having bumps including a contact portion which directly contacts a wafer was prepared.

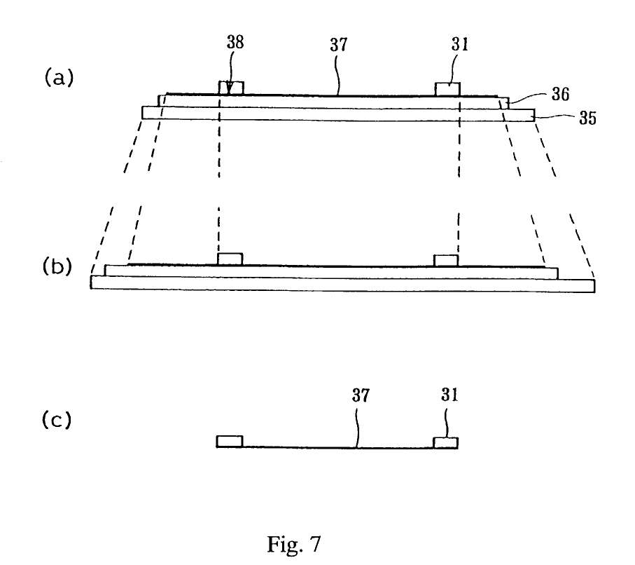

A method of preparing the membrane ring will be described with reference to FIG. 7.

First, as shown in FIG. 7A, a silicon rubber sheet 36 having a uniform thickness of 5 mm is attached onto an aluminum plate 35 having a high flatness.

On the other hand, for example, copper is formed into a film 37 having a thickness of 18 μm on a polyimide film having a thickness of 25 μm by the sputter method or the plating method.

Additionally, the material, forming method, thickness, and the like of the film 37 can appropriately be selected. For examples, a polyimide or capton film having a thickness of about 25 μm (12 to 50 μm), or a silicon rubber sheet having a thickness of about 0.3 mm (0.1 to 0.5 mm) can be used. Examples of a film forming method include: a coating method; and a method of using a commercial film or sheet. Furthermore, the method can comprise: casting the polyimide precursor in a copper foil; subsequently heating, drying, and hardening the polyimide precursor; and forming the film having a structure in which the copper foil is bonded onto the polyimide film. Moreover, a plurality of conductive metal films are successively formed on one surface of the film, and a structure in which a conductive metal layer having a laminated structure is formed on one surface of the film can also be used.

Furthermore, a thin Ni film (not shown) may also be formed between polyimide and Cu for purposes of enhancing the adhesion and preventing the film from being polluted. Additionally, a thin Cr film (not shown) may also be formed between polyimide and Cu for a purpose of forming the thin-film resistance.

Subsequently, the film 37 structured by bonding copper to the polyimide film is adsorbed onto the silicon rubber sheet 36 with a copper side facing downwards and in an uniformly exploded state. In this case, a property of the film 37 adsorbed by the silicon rubber sheet 36 is used. An air layer is expelled and the film is adsorbed without generating any crease or deflection. Thereby, the film is adsorbed in a uniformly exploded state.

Subsequently, an adhesion surface of a circular SiC ring 31 having a diameter of about 8 inches and thickness of about 2 mm is coated with a thin and uniform thermosetting adhesive 38 having a thickness of about 50 to 100 μm, and laid on the film 37. Here, as the thermosetting adhesive 38, an adhesive is used which hardens at a temperature higher than a set temperature of a burn-in test of 80 to 150° C. by 0 to 50° C. In this example, a bond high chip HT-100L (main agent:hardener=4:1) (manufactured by Konishi Co., Ltd.) was used.

Furthermore, an aluminum plate having a high flatness and a weight of about 2.5 kg is laid as a press on the ring 31 (not shown).

The film subjected to the above-described preparation step is heated at a temperature (e.g., 200° C.) which is not less than the set temperature of the burn-in test (80 to 150° C.), for example, for 2.5 hours so that the film 37 is bonded to the ring 31 (FIG. 7B).

In this case, a thermal expansion coefficient of the silicon rubber sheet 36 is larger than that of the film 37. Therefore, the film 37 adsorbed onto the silicon rubber sheet 36 expands by the same degree as that of the silicon rubber sheet 36. That is, as compared with a case in which the film 37 is simply heated at the temperature not less than the set temperature of 80 to 150° C. of the burn-in test, the thermal expansion of the silicon rubber sheet is large and the polyimide film further expands by this stress. The thermosetting adhesive 38 hardens in a large tension, and the film 37 is bonded to the ring 31. Moreover, the film 37 is adsorbed onto the silicon rubber sheet 36 without any crease, deflection, or looseness and in the uniformly exploded state. Therefore, the film 37 can be bonded to the ring 31 without causing any crease, deflection, or looseness in the film 37. Furthermore, since the silicon rubber sheet 36 has a high flatness and elasticity, the film 37 can uniformly and evenly be bonded to the bond surface of the ring 31. A tension of the polyimide film was set to 0.5 kg/cm².

Additionally, when the thermosetting adhesive is not used, the film contracts, the tension weakens, and additionally, a setting time of the adhesive fluctuates with positions. Therefore, the film cannot uniformly or evenly be bonded to the bond surface of the ring.

The structure subjected to the above-described heating/bonding step is cooled at room temperature, and contracted in a preheating state. Thereafter, the film 37 outside the ring 31 is cut/removed along the outer periphery of the ring 31 with a cutter, and the membrane ring is prepared (FIG. 7C).

A step of processing the membrane ring and forming bumps and pads will next be described.

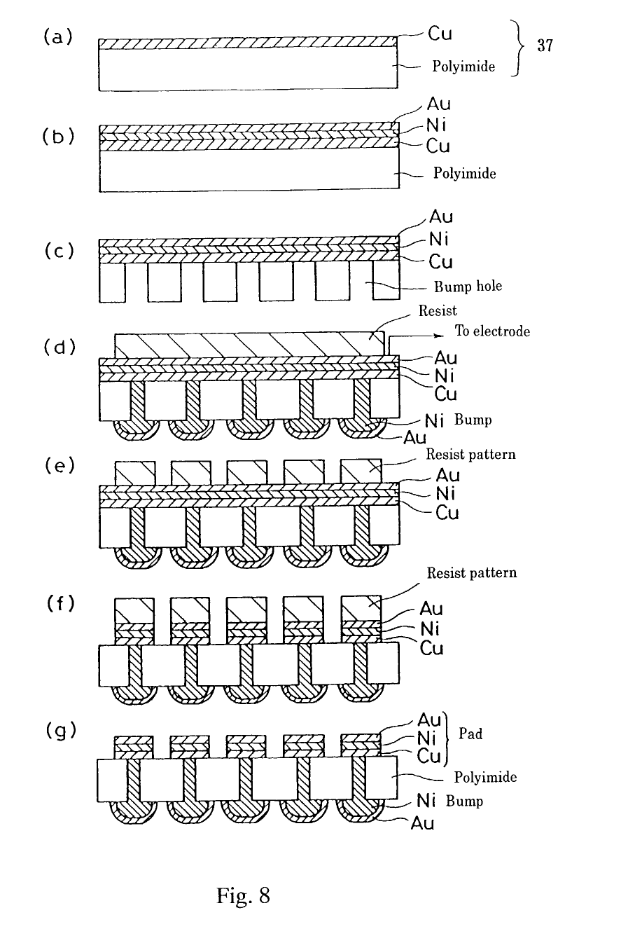

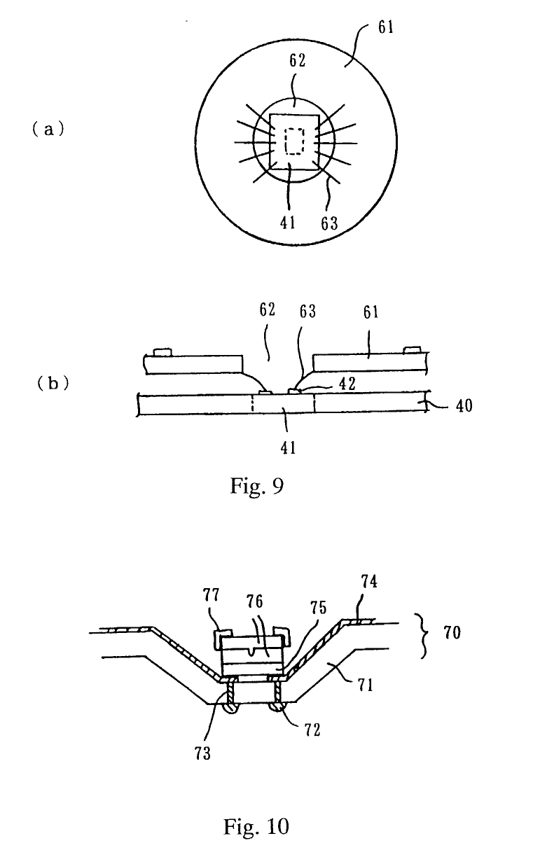

First, on the copper foil (Cu) of the film 37 having a structure in which the copper foil in the membrane ring prepared as described above is bonded to the polyimide film as shown in FIG. 8A, Ni is plated in a range of 0.2 to 0.5 μm, preferably 0.1 to 3 μm by an electric plating as shown in FIG. 8B. Furthermore, Au is formed in a range of 0.1 to 0.5 μm, preferably 0.5 to 2 μm, and an Au/Ni/Cu/polyimide film laminated film structure is formed. Additionally, the Au layer may also be formed in a subsequent step.

Subsequently, as shown in FIG. 8C, an excimer laser is used in predetermined positions of the polyimide film, and bump holes each having a diameter of about 30 μm are formed at a pitch of 267 μm.

Subsequently, as shown in FIG. 8D, in order to prevent the surface of the uppermost layer of the Au film from being plated, a protective film such as a resist is applied to the entire surface of the Au film excluding a portion for use as the electrode in a thickness of about 2 to 3 μm, and the Au film is protected.

Subsequently, the Au film of the uppermost layer is connected to one electrode, and the polyimide film is electrically plated with Ni or an Ni alloy. By this electric plating, the plating grows to fill in the bump holes as shown in FIG. 8D, subsequently reaches the surface of the polyimide film, spreads in an isotropic manner, and grows in a substantially semispherical shape, so that bumps are formed of Ni or the Ni alloy.

Subsequently, an electric plated layer of Au having a film thickness of 1 to 2 μm is formed on the surfaces of the bumps. Thereafter, as not particularly shown, the protective film is peeled off.

Subsequently, the entire surface of the uppermost layer of Au is coated with a new resist, and the resist excluding portions forming the pads is exposed, developed, and removed. Resist patters are formed on the pad forming portions as shown in FIG. 8E.

Subsequently, as shown in FIG. 8F, the Au film is etched with an aqueous iodine/potassium iodine solution, thin Ni and Cu films present between Au and Cu are etched with an aqueous ferric chloride solution, and the structure is well rinsed. Thereafter, the resist is peeled off, and pads are formed of Au/Ni/Cu as shown in FIG. 8G. In this case, when a spray method is used, the etching is preferable with little side etching.

Through the above-described steps, the bumps and pads are formed on the membrane ring, and the membrane ring having bumps is completed.

Assembly Step

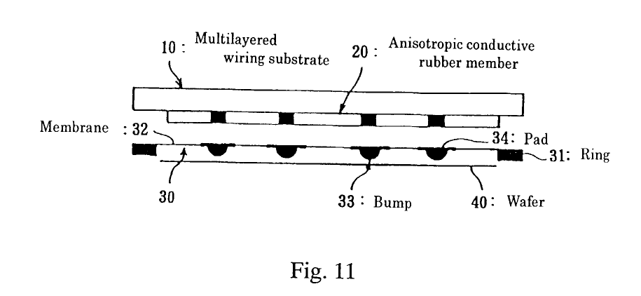

As shown in FIG. 11, the multilayered wiring substrate 10 to which an anisotropic conductive rubber member 20 prepared as described above was attached, and a membrane ring having bumps 30 were positioned and bonded to each other so as to prevent pad electrodes 34 from being detached, so that the wafer level contact board was completed.

Burn-in Test

The electrode terminals on the wafer and bumps 33 of the membrane ring having bumps were positioned with each other and fixed with a chuck, inserted into a burn-in test apparatus in this state, and tested in an operation environment at 125° C. As a result, since the terminating resistance is disposed, the noise (ringing) by the reflection can be reduced, and the transmission loss can be reduced in a high frequency measurement of 100 MHz or more. Therefore, it has been confirmed that it is possible to accurately measure (test) devices such as a microcomputer, ASIC, and memory as compared with a conventional example.

### EXAMPLE 2

When the right-side Ni/Cu/Cr portion shown in FIG. 5 forms the isolated signal pad in the multilayered wiring substrate, and the left-side Ni/Cu/Cr portion forms the isolated GND pad in Example 1, a Cr thin-film resistance of 50 Ω is formed in the entire surface between the portions. Moreover, when the right-side Ni/Cu/Cr portion shown in FIG. 5 forms the isolated signal pad in the membrane ring having bumps, and the left-side Ni/Cu/Cr portion forms the isolated GND pad, the Cr thin-film resistance of 50 Ω is also formed in the entire surface between the portions.

As a result, the characteristic impedance is matched by the Cr thin-film resistance, thereby the noise (ringing) by the reflection can be reduced, and the transmission loss can be reduced. Therefore, it has been confirmed that more accurate measurement (check) of the device is possible as compared with Example 1.

Additionally, the present invention is not limited to the above-described embodiment, and can appropriately be modified within the scope of the present invention.

For example, the resistance can be disposed in the terminal of the signal wire and unmatched position of the characteristic impedance not only in the wafer level contact board described in the above-described embodiment, but also in probe cards such as a burn-in probe card and membrane probe card, contact probe members for checking a CPS, BGA, and IC substrate including a solder ball as a contact point, for a tape carrier for checking one chip burn-in, and for a wafer level bulk CPS check.

Moreover, the laminate number of the wire in the multilayered wiring substrate for the wafer level contact board described in the above-described embodiment is not limited to two layers, and a desired laminate number (e.g., usually two to five layers) may also be set.

In this case, similarly as the steps including and before the step (3) shown in FIG. 6, for second and more layers of the Ni/Cu/Cr multilayered wiring layers, the terminating resistances are disposed between the terminal of the signal common wire and the GND common wire.

Moreover, the glass substrate described in the embodiment is not limited to NA40 manufactured by HOYA Corp., and a material having a thermal expansion coefficient which is the same as or close to the coefficient of Si can be used. In the material, a warp is not generated by any stress, and the material is easily molded. Examples of the material include: ceramic substrates such as SiC, SiN and alumina; other glass substrates whose thermal expansion coefficients are substantially the same as the coefficient of Si in a range of the thermal expansion coefficient of 0.6 to 5 PPM, such as NA35, NA45, SD1 and SD2 manufactured by HOYA Corp., and Pyrex and 7059 manufactured by Coning Co.; a glass ceramic substrate; a resin substrate (particularly for a small substrate); and the like.

Additionally, as compared with the ceramic substrate, the glass substrate, is inexpensive, easily processable, has a satisfactory flatness by a high-precision grinding, is transparent and is therefore easily aligned, can be controlled in the thermal expansion by the material, and is superior in electric insulation. Moreover, nonalkali glass is not adversely affected by surface elution of alkali.

According to the present invention, there can be provided a contact probe member in which a problem of reflection in the terminal of the electrical transmission line is solved.

Moreover, there can be provide a contact probe member in which problems in a characteristic impedance mismatched position are solved.

Furthermore, there can be provided a manufacturing method in which the contact probe member can be realized in a simple process without adding any complicated process.

What is claimed is:

1. A contact probe member comprising:
a plurality of electrodes which corresponds to electrode terminals in a semiconductor device disposed on an insulating substrate; and
a plurality of electrical transmission lines disposed on said insulating substrate and electrically connected to said plurality of electrodes,
wherein a terminating resistance is disposed in a terminal of said electrical transmission line in order to prevent reflection from the terminal of said electrical transmission line.

2. The contact probe member according to claim 1 wherein the terminating resistance is disposed between the terminal of a signal wire and a GND or a GND wire.

3. A multilayered wiring substrate which constitutes a part of a wafer level contact board use for testing together a large number of semiconductor devices formed on a wafer, the multilayered wiring substrate comprising:
a plurality of electrodes which corresponds to electrode terminals on said large number of semiconductor devices disposed on the multilayered wiring substrate;
common wires of each signal, power supply, and GND, which electrically connect said electrodes to one another in common in order to connect the same signal, power supply, and GND to the same positions in each of said large number of semiconductor devices;
branch wires which are branched from said common wires, and which connect said electrodes to the common wires; and
a terminating resistance disposed between the terminal of the signal common wire and the GND common wire.

4. A probe structure of a contact probe member comprising:
a plurality of electrodes which corresponds to electrode terminals in a semiconductor device disposed on an insulating substrate; and
a plurality of electrical transmission lines disposed on said insulating substrate and electrically connected to said plurality of electrodes,
wherein a resistance for matching a characteristic impedance is disposed in a connected position to a line having a different characteristic impedance in said electrical transmission line and/or a connected position to an apparatus having a different characteristic impedance.

5. A wafer level contact board comprising: at least a multilayered wiring substrate for the wafer level contact board; and a membrane ring having bumps serving as a contact portion which directly contacts an element to be tested,
wherein a resistance for matching a characteristic impedance is disposed in a connected position to a line having a different characteristic impedance in an electrical transmission line in the wafer level contact board and/or a connected position to an apparatus having a different characteristic impedance.

6. A manufacturing method of a contact probe member, comprising: a step of forming a wire layer or a metal layer having a single layer structure or a multilayered structure in which two or more different material layers are laminated on an insulating substrate; and a step of etching said wire or metal layer to form a wire (including an electrode) and/or an isolated electrode, the method further comprising:
a step of etching the wire or metal layer in a portion in which a resistance is to be formed in said wire or metal layer and disposing the resistance constituted of a part of the wire or metal layer.
